(19) United States
(12) Patent Application Publication
(10) Pub. No.: US 2009/0087581 A1
(43) Pub. Date: Apr. 2, 2009

(54) MANUFACTURING DIFFRACTIVE OPTICAL ELEMENTS

(76) Inventors: Juan Maria Gonzalez Leal, Puerto Real (ES); Jose Andres Angel Ruiz, Puerto Real (ES)

Correspondence Address: FISH & RICHARDSON P.C., P.O BOX 1022, Minneapolis, MN, 55440-1022, US

(21) Appl. No.: 12/280,319

(22) PCT Filed: Jan. 31, 2007
(86) PCT No.: PCT/ES2007/000052

§ 371 Date: Nov. 25, 2008

(30) Foreign Application Priority Data
Feb. 24, 2006 (ES) P200600446

(51) Int. Cl. B05D 3/06; C23C 16/00

(52) U.S. Cl. 427/555; 118/722

(57) ABSTRACT

A method and related apparatus for registering diffractive optical structures, in which: (a) a transparent substrate is positioned next to a starting material inside a chamber, (b) the starting material is vapourised or sublimated, (c) the vapour phase is deposited on the substrate, and (d) the area of the substrate on which the vapour phase was deposited is irradiated concurrently with a random distribution of the light intensity. The deposit has a diffractive optical functionality owing to the local changes produced in its structure, which are controlled by the distribution of the light intensity used in the production process.

### CROSS-REFERENCE TO RELATED APPLICATIONS

This application is the national stage of International Application No. PCT/ES2007/000052 filed Jan. 31, 2007, which claims priority under 35 U.S.C. § 119(a) to Spanish Application No. P200600446, filed Feb. 24, 2006.

### FIELD OF THE INVENTION

The present invention lies within the field of optical elements with diffractive functions, and methods of manufacturing them.

Optical elements are very important in all technological fields where it is necessary to modulate the spatial distribution of light. Bearing in mind this requirement, it is necessary to optimise techniques of manufacturing simple optical elements and producing optical elements with new functions.

There are a variety of methods for manufacturing diffractive optical elements, and for recording diffractive structures on semiconductor media, which are based on processing a support material using classical photolithographic techniques, or other more modern techniques of laser ablation or holographic recording, all of which are characterized by a sequential (i.e., non-concurrent) nature of the process. In other words, the methods include (a) the prior preparation of the support material, and (b) its subsequent processing.

Furthermore, it is important to mention light-assisted deposition methods, which are widely known and used in planar technologies. In these technologies pulsed lasers are used to deposit conductor, semiconductor and superconductor compounds, which are used in active and passive optical and/or electronic devices. These known techniques avoid the interaction between the laser beam and the vapour phase, or plasma plume, generated from the starting material, so that the configuration of the systems that are used involve the pulsed beam that brings about the ablation of the starting material and the plume of the ejected material being non-collinear, rather than concurrent action on the deposit using light irradiation during its growth.

In the process shown in U.S. Pat. No. 6,766,764, a pulsed laser beam falls on one side of a transparent substrate. Rather than the transparent substrate being designed to act as a support for the deposit and to enable it to be structurally photomoulded during its growth, it is designed to support the starting material. This involves the substrate supporting a layer of a material that is photoevaporable, which in turn supports a layer of material to be deposited on a second substrate. The photoinduced evaporation of the transfer material, through the transparent substrate, brings about the ejection of the material of interest in a localised area of the recipient substrate. Again, this process does not involve any concurrent action on the deposit using light irradiation during its growth.

### SUMMARY OF THE INVENTION

The present invention proposes a light-assisted method of manufacturing deposits of semiconductor compounds that act as a support for diffractive optical structures, various examples of which can take advantage of the following process considerations:

1. Structural fragments of the constituent elements of semiconductor compounds can be ejected from a solid when they are irradiated with light whose photon energy is comparable (in the order of magnitude) to its optical gap, with a high enough intensity. This intensity depends on the type of semiconductor material.

2. The vapour phase, or plasma plume, that is generated condenses on a substrate located in the proximity of the starting material, causing this material to be deposited on the substrate.

3. The morphology of the deposit is related to the characteristics of the plume or vapour phase, which depend on the spatial light intensity distribution on the target material, the spectral radiance of the light source, the distance between the target material and the substrate, the pressure and the atmosphere in the chamber, the temperature of the starting material, the temperature of the substrate, and the irradiation time.

4. Concurrent illumination of the deposit during its growth affects the physicochemical properties of the material that forms said deposit as a consequence of its effect on the structure of the material being formed (see FIG. 1). The creation of structures with a diffractive function may be controlled through the spatial light intensity distribution that concurrently falls on the deposit area of the substrate, and they may cover a large interval of diffractive gaps. These may be phase structures (consequence of local changes in the thickness and/or the refractive index on the deposit) and/or amplitude structures (consequence of local changes in the absorption coefficient on the deposit).

We propose a method for manufacturing diffractive optical elements in a simple and economical way, including the following steps: (a) situating a transparent substrate close to a target material, both of which are situated inside a chamber, (b) causing vaporisation or sublimation of the target material, (c) depositing this vapour phase on the substrate, and (d) concurrently irradiating the area of the substrate where the deposit occurs with a selected light intensity distribution. The deposit presents a diffractive optical function due to the local changes induced in its structure, governed by the light intensity distribution used in the manufacturing process.

In a preferred embodiment of the invention, which is not limiting in terms of the material used or the configuration of the manufacturing system, a continuous laser beam, with a wavelength of 532 nm and a spatial light intensity distribution with its phase following a pattern of Fresnel zones, perpendicularly crosses a transparent substrate with planoparallel sides before reaching a target material situated a few millimetres from the substrate. Said modulation may be achieved with a set of optical elements as shown in FIG. 3. Said target material is a disc (wafer) with a diameter of around 1 cm and a thickness of 2 mm, made from compacted powder of an amorphous V-VI semiconductor alloy (e.g. an alloy of As and S), which is sensitive to the photon energy of light radiation from a Nd:YAG laser (2.33 eV). The sides of the substrate and the wafer that face each other are parallel.

The above-described configuration produces a deposit with an aspheric morphology, which supports a distribution of concentric rings in the form of surface reliefs of high spatial frequency, as shown in FIG. 2. Said optical elements combine the refractive function of the profile of low spatial frequency with the added diffractive function of high spatial frequency using Fresnel zones. This combination may be used to compensate e.g. chromatic aberrations that these optical structures present when they perform their characteristic optical function independently.

The transparency of V-VI semiconductors in the infrared (IR) spectral region guarantees the stability of the optical elements manufactured in this spectral window, therefore making it the preferred working spectral region.

However, we have observed that the optical elements produced according to the above-described preferred embodiment present a greater optical transparency and a higher damage threshold to the laser radiation used in the manufacturing process compared to that of the starting material, possibly due to concurrent illumination of the material being deposited. In experiments, an increase of more than one order of magnitude has been observed in the damage intensity in alloys with a composition of As₂₀S₈₀, in relation to the intensity supported by the starting material.

Furthermore, it has been shown that coating an amorphous chalcogenide deposit with a layer of polymethyl methacrylate (PMMA) increases by several orders of magnitude the damage threshold to radiation for which the chalcogenide alloy would be sensitive without any coating.

In view of such findings, both of our own and as reported in the literature, it can be inferred that although the IR region is the preferred window, it should not be considered the only one.

### BRIEF DESCRIPTION OF THE FIGURES

FIG. 1 shows x-ray diffraction patterns corresponding to: (a) an ingot of the amorphous alloy As₂₀S₈₀, (b) a wafer made from the compacted powder of this material, which constitutes the starting material used in the real examples described in this patent, and (c) a deposit of this starting material carried out using the method disclosed herein. The results show the structural difference between the deposited material and the starting material.

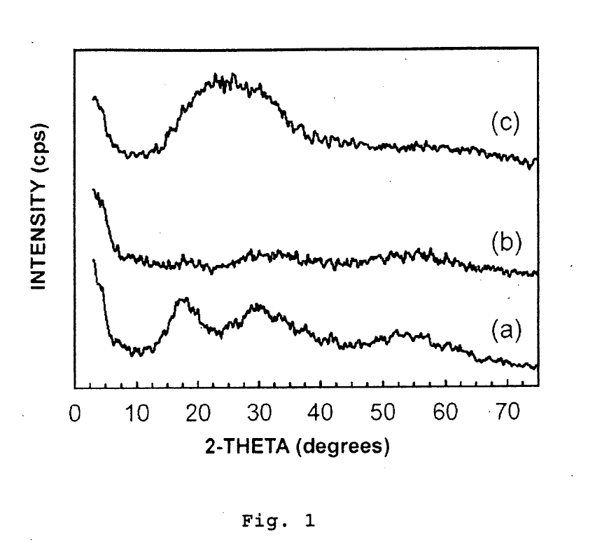

FIG. 2 is a diagram showing the combination of the refractive function of an aspheric optical element (a) and the diffractive function of an optical element consisting of Fresnel zone plates (b), to form an optical element as shown in (c), with the cross section shown in (d).

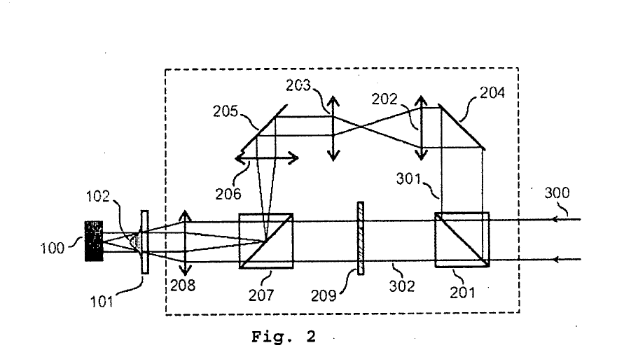

FIG. 3 illustrates an example of a combination of optical elements that produces a modulation in the light intensity in the form of Fresnel zone plates. Said radiation acts on the deposit being formed, to manufacture an optical element that combines refractive and diffractive functions.

FIG. 4 is a cross-sectional diagram of a system for producing diffractive optical elements in a collinear configuration, wherein a single light beam generates the vapour phase of the starting material and concurrently irradiates the deposit during its growth.

FIG. 5 is a cross-sectional diagram of a system for producing diffractive optical elements in a collinear configuration, wherein more than one source of light radiation is involved in the process.

FIG. 6 is a cross-sectional diagram of a system for producing diffractive optical elements in a non-collinear configuration, wherein only one source of light radiation is involved in the ejection of the starting material, and an additional source of radiation is involved in creating diffractive structures on the deposit.

FIG. 7 is a cross-sectional diagram of a system for producing diffractive optical elements in a non-collinear configuration, wherein two or more sources of light radiation are involved in the ejection of the starting material, and two or more additional sources of radiation are involved in creating diffractive structures on the deposit.

### DETAILED DESCRIPTION

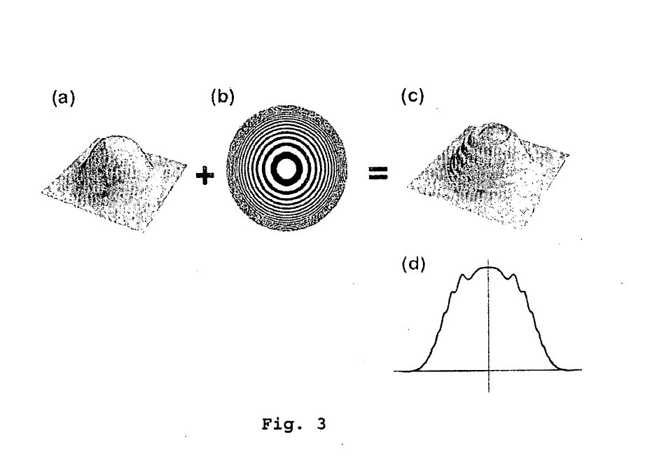

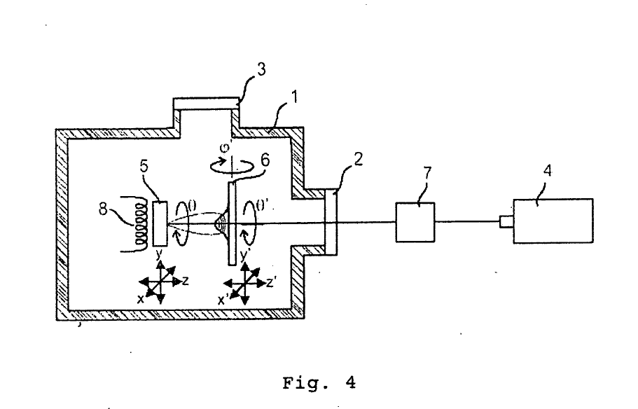

FIG. 4 shows a first method for manufacturing optical elements that combine refractive and diffractive functions. With reference to this figure, the system features a chamber 1 with transparent windows 2 and 3, and a source of continuous or pulsed light radiation 4, a starting material 5, and a substrate 6 which is transparent to the radiation from light source 4, and also transparent to the working radiation for which the optical element to be manufactured is designed. The spatial light intensity distribution on the deposit is controlled by an opto-mechanical modulation means 7, which is a combination of optical (lenses, mirrors, filters, beam splitters, masks, spatial light, phase and amplitude modulators, etc.) and/or mechanical (linear positioning stages, angular positioning stages, mechanical spatial light modulators, etc.) elements for spatially modulating the radiation according to the required diffractive pattern. In FIG. 3 a combination of optical elements is shown that produces a modulation in the light intensity in the form of Fresnel zone plates. This combination serves as an example of the opto-mechanical modulation means 7, 10, 13 and 16, which are shown in FIGS. 4, 5, 6 and 7.

The method contemplates the possibility of several beams emerging from opto-mechanical modulation means 7 and falling on the area of the substrate where the material will be deposited, to record, for example, a Bragg grating, controlling the spacing of the grating by controlling the angle between the interfering beams. The light beam from light source 4 (or beams, bearing in mind the above) enters the chamber through the window 2, and crosses the substrate 6 before falling on the starting material 5, bringing about its ejection. The generation of this plume can be assisted by heat from a heat source 8. The deposition can also be thermally assisted by supplying heat to the substrate, in a similar way to heat source 8 (not shown in FIG. 4). The deposition is carried out at a controlled pressure and atmosphere.

The starting material 5, which is situated inside the chamber, can be an ingot of a semiconductor alloy, or a wafer made from the alloy to be deposited in powder form. The wafer can be a homogeneous or heterogeneous mixture of semiconductor alloys containing a chalcogen element (O, S, Se and/or Te) and other reactants, such as Ge, Ga, Si, P, As, Sb, I, Pm, Sm, Eu, Er, which act as both passive and active elements for a determined light radiation. The amorphous alloy As₂₀S₈₀ constitutes the starting material. The starting material is supported by support means that give it freedom to move in the three Cartesian directions, x, y, z, and to rotate around an axis that is perpendicular to its surface, θ.

The substrate 6 is supported by support means that give it freedom to move in the three Cartesian directions, x′, y′, z′, as well as to rotate around an axis that is perpendicular to its surface, θ′, and around an axis that is parallel to its surface, φ′, in a way that is not integral to the starting material.

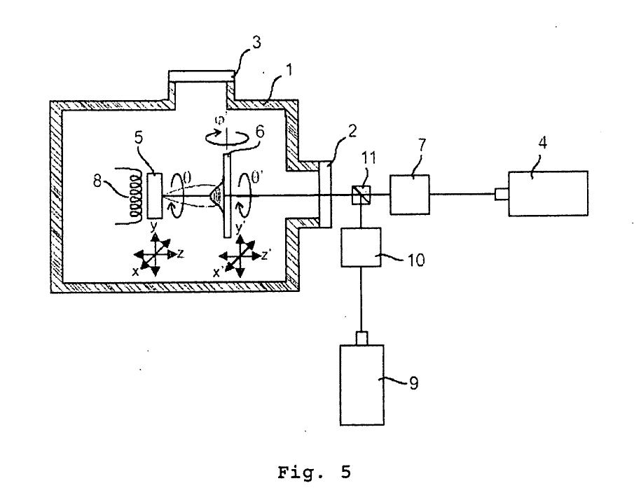

FIG. 5 shows a second method for manufacturing optical elements that combine refractive and diffractive functions. With reference to this figure, and similarly to that described for FIG. 4, the system features a chamber 1 with transparent windows 2 and 3, a first source of continuous or pulsed light radiation 4, a second source of continuous or pulsed light radiation 9, a starting material 5, and a substrate 6 that is transparent to the radiation from 4 and 9, and also transparent to the working radiation for which the optical element to be manufactured is designed. The spatial light intensity distribution of the radiations from light sources 4 and 9 is controlled by first 7 and second 10 opto-mechanical modulation systems that are combinations of optical (lenses, mirrors, filters, beam splitters, masks, spatial light, phase and amplitude modulators, etc.) and/or mechanical (linear positioning stages, angular positioning stages, mechanical spatial light modulators, etc.) elements for spatially modulating the radiation according to the desired diffractive pattern. As in the above example, the method contemplates the possibility of several light beams emerging from 7 and 10. The beams from sources 4 and 9 are directed into the chamber through the window 2 via the beam splitter 11, with either coinciding or non-coinciding directions of propagation. Both light beams from sources 4 and 9 cross the substrate 6, and at least one of them brings about the ejection of the starting material 5. The generation of the plume may be assisted by heat using a heat source 8. The deposition may also be thermally assisted by supplying heat to the substrate in a similar way to heat source 8 (not shown in FIG. 5). The deposition is carried out at a controlled pressure and atmosphere.

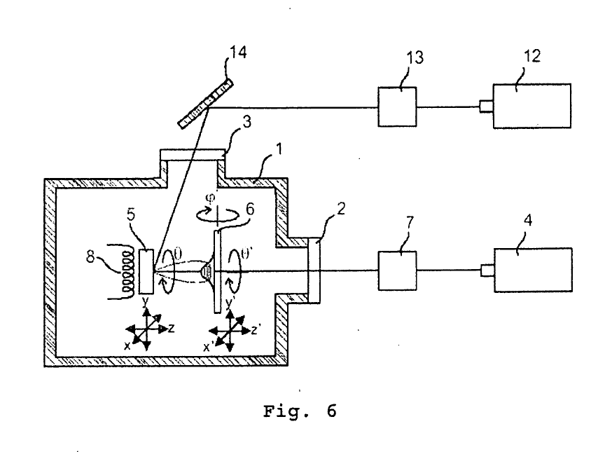

FIG. 6 shows a third method for manufacturing optical elements that combine refractive and diffractive functions. With reference to this figure, and similarly to that described for FIGS. 4 and 5, the system consists of a chamber 1 with transparent windows 2 and 3, and a continuous or pulsed source of light radiation 4, a second source of continuous or pulsed light radiation 12, a starting material 5, and a substrate 6 that is transparent to the radiation from light source 4, and also transparent to the working radiation for which the optical element to be manufactured is designed. The spatial light intensity distribution of the radiations from light sources 4 and 12 is controlled by first 7 and second 13 opto-mechanical modulation systems that are combinations of optical (lenses, mirrors, filters, beam splitters, masks, spatial light, phase and amplitude modulators, etc.) and/or mechanical (linear positioning stages, angular positioning stages, mechanical spatial light modulators, etc.) elements for spatially modulating the radiation.

The beam from source 4 enters the chamber through the window 2, and crosses the substrate 6 to irradiate the material that is to be deposited. The beam from source 12 enters the chamber through the window 3, via the mirror 14, and falls on the starting material, bringing about its ejection. The generation of the plume can be assisted by heat from a heat source 8. The deposition can also be thermally assisted by supplying heat to the substrate, in a similar way to heat source 8 (not shown in FIG. 6). The deposition is carried out at a controlled pressure and atmosphere.

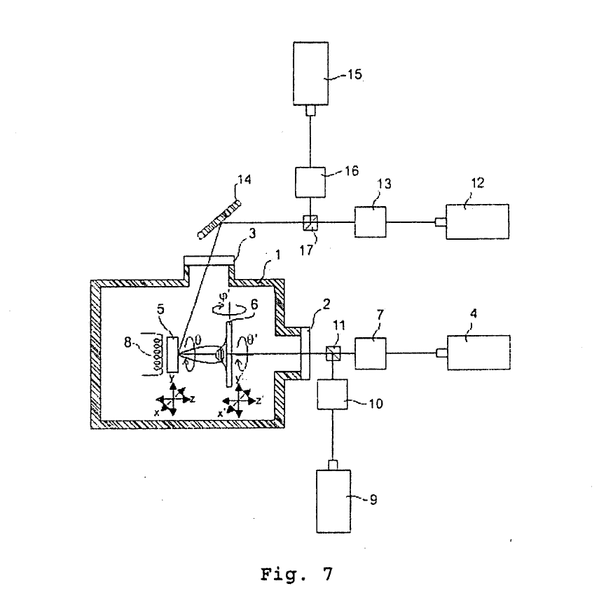

FIG. 7 shows a fourth method, which is more general, for manufacturing optical elements that combine refractive and diffractive functions. With reference to this figure, and similarly to that described for FIGS. 4, 5 and 6, the system features a chamber 1 with transparent windows 2 and 3 first and second sources of continuous or pulsed light radiation 4 and 9, which are responsible for recording diffractive structures, third and fourth sources of continuous or pulsed light radiation 12 and 15, which are responsible for bringing about the ejection of the starting material 5, and a substrate 6 that is transparent to the radiation from 4 and 9, and also transparent to the working radiation for which the optical element to be manufactured is designed. The spatial light intensity distribution of the radiations from light sources 4, 7, 12 and 15 is controlled by opto-mechanical modulation systems 7, 10, 13 and 16, respectively, which are combinations of optical (lenses, mirrors, filters, beam splitters, masks, spatial light, phase and amplitude modulators, etc.) and/or mechanical (linear positioning stages, angular positioning stages, mechanical spatial light modulators, etc.) elements for spatially modulating the radiation. The beams from sources 4 and 9 are directed into the chamber through the window 2 via the beam splitter 11, with either coinciding or non-coinciding directions of propagation. The beams from sources 12 and 15 are combined by the beam splitter 17 and enter the chamber through the window 3, via the mirror 14, falling on the starting material and bringing about its ejection. The generation of the plume can be assisted by heat from a heat source 8. The deposition can also be thermally assisted by supplying heat to the substrate, in a similar way to heat source 8 (not shown in FIG. 7). The deposition is carried out at a controlled pressure and atmosphere.

In some examples the apparatus for manufacturing a diffractive optical element includes a system for injecting gases (for example He, Ne, Ar, H₃As, H₂S, H₂Se), not shown in the figures.

A particular embodiment is described below to illustrate a method for manufacturing an aspheric lens that combines refractive and diffractive functions, which is highly transparent in the IR region, with a high damage threshold. The beam is treated according to the optical assembly shown in FIG. 3. The starting material 100, in this case, is a circular wafer with a 13 mm diameter, made from 125 mg of powder, compacted for 10 minutes with a 10 ton load, of an amorphous chalcogenide alloy with a composition of As₂₀S₈₀, which presents an optical gap of 2.1 eV. The pressure in the chamber is reduced to below 10⁻⁴ mbar. The light radiation 300 comes from a Nd:YAG continuous laser generator (not shown) emitting at 532 nm (2.33 eV), with a power of 1.5 W. The beam is treated according to the optical assembly shown in FIG. 3. The beam is filtered using a spatial filter, and collimated with a lens that has a focal length of 150 mm (not shown in FIG. 3). The beam is split using a beam splitter cube 201. The section of one of the emerging beams 301 is reduced using a combination of a lens 202 with a focal length of 150 mm and another lens 203 with a focal length of 75 mm, and mirrors 204 and 205 are used to direct it. This beam is focused by means of a lens 206 with a focal length of 50 mm, and it is directed at a second beam splitter 207. The transversal component that results from the interaction of the beam 301 with the beam splitter cube 207 is collimated by means of a lens 208 with a focal length of 50 mm. This lens constitutes the outlet of the optical assembly before the resulting radiation enters the chamber. Meanwhile, the second beam emerging from the first beam splitter 302 passes through an attenuator 209 to compensate for the losses suffered by beam 301. The beam 302 crosses the second beam splitter 207 and is focused by lens 208 with a 50 mm focal length that faces the chamber. Beam 302 mainly induces ejection of the starting material. The material ejected from the surface of the wafer generates a distribution of the vapour phase in the form of a spindle (plume) that is perpendicular to the irradiated surface of the wafer. The transparent substrate 101 is situated in the chamber perpendicular to the optical axis of the above-described assembly, at a distance of 2 mm from the starting material, and it is passed through by the radiation generated at the outlet of said assembly. The vapour phase of this material 102 condenses on the side of the substrate that faces the starting material, presenting an aspheric spatial distribution on its surface. The concurrent action of the light radiation, which is modulated according to the pattern generated by beams 301 and 302 falling on the deposit, produces a surface relief on the aspheric surface in the form of Fresnel zone plates. It cannot be ruled out that, as well as producing the surface relief that is observed, the light radiation brings about localised changes in the refractive index and/or the absorption coefficient in the deposited material. If it were not affected by the refractive profile, the created diffractive element would act as a phase diffractive lens with a focal length of approximately 25 mm.

The conditions of the system may be adjusted to deposit a uniform profile or a profile of a variable thickness, concentrated on a localised region of the substrate or extended across it according to any desired distribution. The area covered by the deposit and the thickness profiles may be controlled by moving the light beam over the surface of the starting material and/or the substrate via the means of support that give the starting material and the substrate the degrees of freedom x, y, z, θ, x′, y′, z′, 0′, φ′, respectively, which are shown in the diagrams in FIGS. 4, 5, 6 and 7.

1-19. (canceled)

20. A method of manufacturing diffractive optical elements, the method comprising:
positioning a substrate, which is transparent to both a working radiation for which the optical element being manufactured is designed and a radiation to be employed in the method, close to a starting material inside a chamber;
spatially modulating a radiation from at least one source of light radiation according to a desired pattern of diffraction;
irradiating the substrate such that the modulated radiation crosses the substrate;
exposing the starting material to the modulated radiation transmitted through the substrate, in a manner than creates a vapour phase of the starting material; and
depositing the vapour phase of the starting material onto the substrate while generating a diffractive structure from the deposited material and concurrently irradiating the deposited material through the substrate with the modulated radiation.

21. The method of claim 20, wherein the modulated radiation is either continuous or pulsed.

22. The method of claim 20, wherein the modulated radiation is either monochromatic or polychromatic.

23. The method of claim 20, wherein the modulated radiation is either coherent or incoherent.

24. The method of claim 20, wherein the starting material comprises an ingot or wafer made from pressed powder of material to be deposited.

25. The method of claim 20, wherein the starting material comprises a homogeneous or heterogeneous mixture of semiconductor alloys containing a chalcogen element and other reactants that function as both passive and active elements with respect to a predetermined light radiation.

26. The method of claim 20, wherein the deposition is carried out under a controlled pressure and atmosphere.

27. The method of claim 20, wherein exposing the starting material to the modulated radiation creates a vapour phase of the starting material by combined heating and light radiation.

28. The method of claim 20, wherein irradiation of the substrate is performed while the substrate is at a temperature other than room temperature.

29. The method of claim 20, wherein facing sides of the starting material and the substrate are parallel while the vapour phase of the starting material is deposited.

30. An apparatus for manufacturing diffractive optical elements, the apparatus comprising:
a chamber with at least one transparent window;
a vacuum system;
a source of light radiation;
a substrate that is transparent to both a working radiation for which the optical element to be manufactured is designed and to radiation from the source of light radiation, a surface of said substrate being situated in an optical path of the radiation from the source of light radiation;
a mechanical support, positioned inside the chamber, which supports the substrate and enables movement of the substrate in three orthogonal directions as well as enabling the substrate to rotate both around an axis that is perpendicular to said substrate surface, and around an axis that is parallel to said substrate surface;
a starting material, positioned in an optical path of radiation from the source transmitted through the substrate, the starting material positioned sufficiently close to the substrate that a vapour phase of the starting material generated by irradiation of a surface of the starting material by the radiation condenses on the substrate;
a mechanical support, positioned inside the chamber, which supports the starting material and enables movement of the starting material in three orthogonal directions, as well as enabling the starting material to rotate, independent of the substrate, around an axis that is perpendicular to said surface of the starting material;
an opto-mechanical radiation modulator, positioned outside the chamber, which modulates a spatial distribution of the light radiation incident to the substrate, in accordance with a desired diffractive pattern.

31. The apparatus of claim 30, further comprising a gas injection system.

32. The apparatus of claim 30, further comprising a heat source that heats the starting material.

33. The apparatus of claim 30, further comprising a heat source that heats the substrate.

34. The apparatus of claim 30, comprising multiple sources of light radiation that causes ejection of the starting material.

35. The apparatus of claim 30, comprising multiple sources of light radiation that generates diffractive structures.

36. The apparatus of claim 34 or claim 35, wherein radiations generated by the multiple sources of light radiation are identical in terms of coherence, chromaticity and time regime.

37. The apparatus of claim 34 or claim 35, wherein radiations generated by the multiple sources of light radiation are different in terms of direction of propagation, intensity, coherence, chromaticity and time regime.
